(19) United States
(12) Patent Application Publication
(10) Pub. No.: US 2018/0233902 A1
(43) Pub. Date: Aug. 16, 2018

(54) GROUND FAULT DETECTION DEVICE, COMMUNICATION DEVICE, METHOD FOR CONTROLLING SAME, LOAD DEVICE, SWITCH AND NON-TRANSITORY COMPUTER-READABLE RECORDING MEDIUM

(71) Applicant: OMRON Corporation, KYOTO (JP)

(72) Inventors: Akihiko SANO, Uji-shi, KYOTO (JP); Kosuke MORITA, Tokorozawa-shi, SAITAMA (JP); Akihiro FUNAMOTO, Soraku-gun, KYOTO (JP)

(73) Assignee: OMRON Corporation, KYOTO (JP)

(21) Appl. No.: 15/751,159

(22) PCT Filed: Mar. 9, 2017
(86) PCT No.: PCT/JP2017/009508

§ 371 Date: Feb. 7, 2018

(30) Foreign Application Priority Data
Apr. 4, 2016 (JP) 2016-075285

(51) Int. Cl. H02H 7/20; H02H 3/16; G01R 31/02; H01L 31/02; H02S 50/10; H02J 3/38; H02J 7/00

(52) U.S. Cl. CPC H02H 7/20; H02H 3/16; G01R 31/025; H02J 7/0052; H02S 50/10; H02J 3/383; H01L 31/02021

(57) ABSTRACT

According to the present invention, a solar cell string has a plurality of solar cell parts connected in series. In each of the solar cell parts, a solar cell module is connected to/separated from a cable run by an optimizer. A ground fault detection device instructs the optimizer to perform switching to the connection or the separation, and, after the instruction, determines the presence/absence of a ground fault in the solar cell string.

### TECHNICAL FIELD

The present invention relates to a ground fault detection device that is applied to a direct current power supply system including a direct current power supply string such as a solar cell string.

### BACKGROUND ART

A solar power generation system includes a solar cell array, the solar cell array is configured by connecting a plurality of solar cell strings in parallel, and each solar cell string is configured by connecting a plurality of solar cell modules in series. As an example, direct current power generated in each solar cell string is converted to appropriate direct current power and/or appropriate alternating current power by a power conditioning system (PCS).

An electrical path of the solar cell string is electrically insulated (hereinafter simply referred to as “insulated”) by an arbitrary sealing material. However, for some reasons, when insulation resistance between a certain place in the electrical path of the solar cell string and the earth decreases, a ground fault occurs at that place.

Therefore, in the related art, a ground fault detection device that detects a ground fault is provided in a solar power generation system, as disclosed in Patent Literatures 1 and 2. Specifically, the ground fault detection device of Patent Literature 1 measures a voltage change or a current change in a closed circuit formed of a solar cell string, a ground fault resistor, and a ground fault detection device, to determine whether there is a ground fault.

Further, a system interconnection inverter of Patent Literature 2 converts direct current power input from a direct current power supply to alternating current power via a converter circuit and an inverter circuit of which an input and an output are not isolated from each other, and outputs the alternating current power to a grounded grid. The grid interconnection inverter includes ground fault detection means for detecting a ground fault of the direct current power supply. Specifically, the ground fault detection means detects a direct current component of a difference current between a current on a positive line and a current on a negative line on the input side, and performs a ground fault determination according to whether or not a detected value is equal to or higher than a predetermined level. Note that the ground fault detection means may detect a direct current component of a difference current between a current on a positive line and a current on a negative line on the output side, and perform a ground fault determination according to whether or not a detected value is equal to or higher than a predetermined level.

### CITATION LIST

### Patent Literature

[Patent Literature 1] Japanese Patent Application Laid-Open (JP-A) No. 2012-119382 (published Jun. 21, 2012)

[Patent Literature 2] Japanese Patent Application Laid-Open (JP-A) No. 2001-275259 (published Oct. 05, 2001)

[Patent Literature 3] U.S. Patent Application Publication No. 2013/0307556 (published Nov. 21, 2013)

[Patent Literature 4] Published Japanese Translation of the PCT International Publication No. 2012-510158 (published Apr. 26, 2012)

### SUMMARY OF INVENTION

### Technical Problem

However, although the ground fault detection device of the related art can determine the presence or absence of the ground fault, it cannot easily specify the position at which the ground fault occurs in the solar cell string.

The present invention has been made in view of the above problems, and an object of the present invention is to provide, for example, a ground fault detection device capable of accurately detecting a ground fault in a direct current power supply string such as a solar cell string.

### Solution to Problem

In order to solve the above problem, a ground fault detection device according to the present invention is applied to a direct current power supply system including a load device that converts or consumes direct current power input to an input terminal, an electrical path connected to the input terminal, and a direct current power supply string in which a plurality of direct current power supply pails are connected in series, and each of the direct current power supply parts includes a direct current power supply module that generates or charges and discharges power, and a switch that connects or disconnects the direct current power supply module to or from the electrical path. The ground fault detection device includes a switching instruction part that instructs the switches to switch between connection and disconnection, and a ground fault determination part that determines the presence or absence of a ground fault of the direct current power supply string after the instruction of the switching instruction part.

A method for controlling a ground fault detection device according to the present invention is a method for controlling a ground fault detection device that is applied to the direct current power supply system having the above configuration, the method including: a switching instruction step of instructing the switches to switch between connection and disconnection; and a ground fault determination step of determining the presence or absence of a ground fault of the direct current power supply string after the instruction of the switching instruction part.

In order to solve the above-described problems, a communication device according to the present invention is applied to a direct current power supply system including a load device having the above configuration, an electrical path having the above configuration, a direct current power supply string having the above configuration, and a ground fault detection device that detects a ground fault of the direct current power supply string, the communication device including a switching instruction part that instructs the switches to switch between connection and disconnection, and the switching instruction part notifies the ground fault detection device that the switching has been instructed.

A method for controlling a communication device according to the present invention is a method for controlling a communication device that is applied to a direct current power supply system having the above configuration, and includes a switching instruction step of instructing the switches to switch between connection and disconnection, in which the switching instruction step includes notifying the ground fault detection device that the switching has been instructed.

### ADVANTAGEOUS EFFECTS OF INVENTION

The ground fault detection device according to the present invention has an effect that a ground fault can be accurately detected by changing a connection form of the direct current power supply module in the direct current power supply string to detect the ground fault.

Further, the communication device according to the present invention has an effect that a ground fault can be accurately detected by changing the connection form of the direct current power supply module in the direct current power supply string to detect the ground fault of the direct current power supply string.

### BRIEF DESCRIPTION OF THE DRAWINGS

FIG. 1 is a schematic circuit diagram illustrating a configuration of a solar power generation system according to an embodiment of the present invention.

FIG. 2 is a schematic circuit diagram illustrating a configuration of an optimizer in the solar power generation system.

FIG. 3 is a block diagram illustrating a configuration of a ground fault detection device in the solar power generation system.

FIG. 4 is a flowchart illustrating a flow of a ground fault detection process in the ground fault detection device.

FIG. 5 is a flowchart illustrating a flow of a process of specifying a position of a ground fault in a ground fault detection device of a solar power generation system according to another embodiment of the present invention.

FIG. 6 is a schematic circuit diagram illustrating a configuration of a solar power generation system according to another embodiment of the present invention.

FIG. 7 is a flowchart illustrating a flow of a process related to a ground fault in the ground fault detection device of the solar power generation system.

### DESCRIPTION OF PREFERRED EMBODIMENTS

Hereinafter, embodiments of the present invention will be described in detail. For convenience of description, members having the same functions as members shown in the respective embodiments are denoted with the same reference signs, and description thereof will be appropriately omitted.

### First Embodiment

### (Overview of Solar Power Generation System)

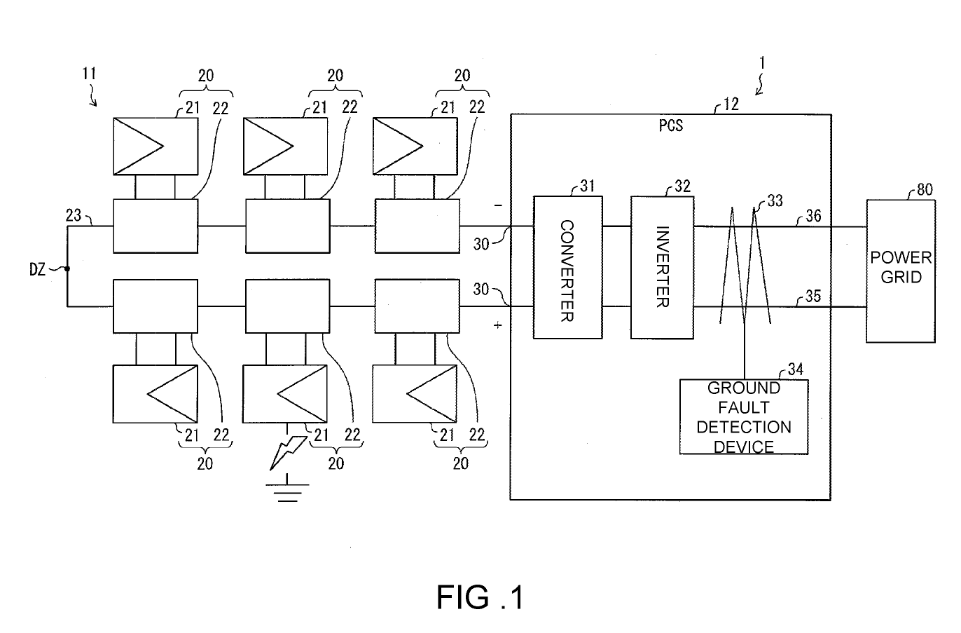

FIG. 1 is a schematic circuit diagram illustrating a configuration of a solar power generation system according to an embodiment of the present invention. As illustrated in FIG. 1, a solar power generation system (direct current power supply system) 1 includes a solar cell string (direct current power supply string) 11 and a PCS (load device) 12.

The solar cell string 11 is formed by connecting a large number (plurality) of solar cell parts (direct current power supply parts) 20 in series. The solar cell string 11 is connected to an input terminal 30 of the PCS 12 via an electrical path 23.

The solar cell part 20 includes a solar cell module (direct current power supply module) 21 and an optimizer (switch) 22. The solar cell module 21 includes a plurality of solar cells (not illustrated) connected in series, and is formed in a panel shape. The optimizer 22 optimizes power from the solar cell module 21 and supplies the power to the electrical path 23 of the solar cell string 11. Thus, it is possible to improve efficiency of power output from the solar cell string 11 to the PCS 12. Details of the optimizer 22 will be described below.

The PCS 12 converts the direct current power input from the solar cell string 11 to the input terminal 30 into predetermined alternating current power. The converted alternating current power is output to and consumed by an external power grid (load device) 80.

The PCS 12 converts the direct current power input from the solar cell string 11 to the input terminal 30 into predetermined alternating current power and outputs the alternating current power to the external power grid (load device) 80. Specifically, the PCS 12 includes a converter 31 and an inverter 32.

The converter 31 is a circuit that converts the direct current power from the solar cell string 11 into predetermined direct current power (DC/DC conversion) and is, for example, a step-up chopper. The direct current power converted by the converter 31 is supplied to the inverter 32.

The inverter 32 is a circuit that performs a conversion operation (DC/AC conversion) for converting the direct current power supplied from the converter 31 into predetermined (for example, a frequency of 60 Hz) alternating current power. The alternating current power converted by the inverter 32 is supplied to the external power grid 80.

Thus, by providing the PCS 12, it is possible to convert the direct current power generated by the solar cell string 11 into the alternating current power having a predetermined voltage and frequency allowing system interconnection with the power grid 80.

In the embodiment, the PCS 12 includes a zero-phase current transformer (ZCT) 33 and a ground fault detection device 34 in order to detect a ground fault in the solar cell string 11.

The ZCT 33 is a current sensor that is used for detection of a ground fault. In a normal case, currents flowing through two electrical paths 35 and 36 have opposite directions and the same magnitude. However, when a ground fault occurs, the currents have different magnitudes. Accordingly, a magnetic flux is induced in the ZCT 33 and a current flows in the ground fault detection device 34.

The ground fault detection device 34 detects a ground fault on the basis of the current from the ZCT 33. Specifically, when a value of the current from the ZCT 33 is equal to or greater than a predetermined value, the ground fault detection device 34 determines that a ground fault has occurred (the presence of a ground fault). Details of the ground fault detection device 34 will be described below.

In the embodiment, the ground fault detection device 34 is communicably connected to the optimizer 22, and detects a ground fault with high accuracy in cooperation with the optimizer 22. It is preferable that the ground fault detection device 34 and the optimizer 22 be communicably connected over a communication network. Examples of the communication network include a wired local area network (LAN) on the basis of power line communications (PLC) using the electrical path 23, and a wireless LAN (IEEE 802.11).

### (Configuration of Optimizer)

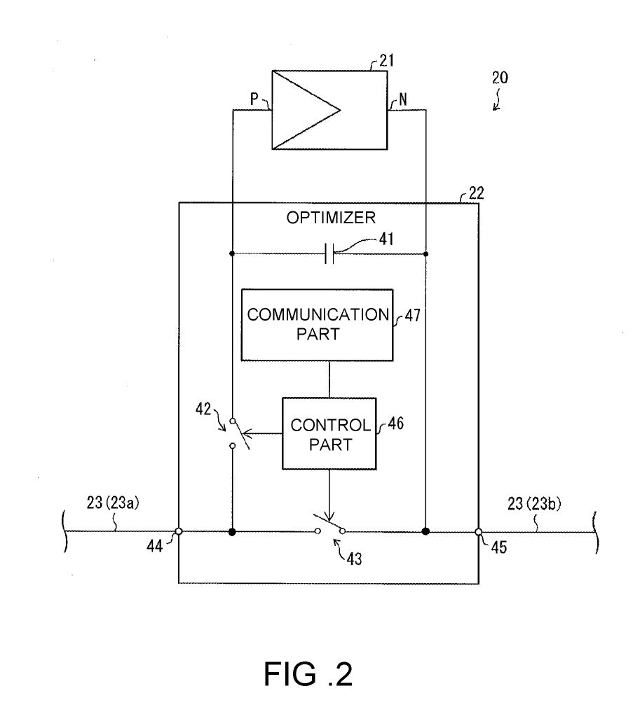

FIG. 2 is a schematic circuit diagram illustrating the configuration of the optimizer 22. As illustrated in FIG. 2, the optimizer 22 includes a capacitor 41, a first switch circuit 42, a second switch circuit 43, a first connection terminal 44, a second connection terminal 45, a control part 46, and a communication part 47.

The solar cell module 21 and the optimizer 22 are inserted in the electrical path 23. A positive terminal P of the solar cell module 21 is connected to one of the electrical paths 23a via the first switch circuit 42 and the first connection terminal 44 of the optimizer 22. A negative terminal N of the solar cell module 21 is connected to the other electrical path 23b via the second connection terminal 45 of the optimizer 22. The connection terminals 44 and 45 are connected via the second switch circuit 43.

The first switch circuit 42 electrically disconnects the solar cell module 21 from the electrical path 23. The second switch circuit 43 electrically connects one of the electrical paths 23a to the other electrical path 23b when the solar cell module 21 is electrically disconnected from the electrical path 23 by the first switch circuit 42. The first switch circuit 42 and the second switch circuit 43 operate on the basis of an instruction from the control part 46. Specifically, the first switch circuit 42 and the second switch circuit 43 include, for example, a switching element.

The capacitor 41 is connected in parallel to the solar cell module 21 on the side of the solar cell module 21 relative to the first switch circuit 42. The capacitor 41 charges or discharges electric energy from the solar cell module 21.

The control part 46 controls overall operations of the various components in the optimizer 22, and is configured of, for example, a computer including a central processing unit (CPU) and a memory. Operation control of various configurations is performed by causing the computer to execute a control program.

The communication part 47 performs data communication with the external ground fault detection device 34. The communication part 47 converts various pieces of data received from the control part 46 into a format suitable for data communication and then transmits the data to the ground fault detection device 34. Further, the communication part 47 converts the various pieces of data received from the ground fault detection device 34 into a data format inside the device, and then transmits the data to the control part 46.

Other configurations in the optimizer 22 are well known from, for example, Patent Literatures 3 and 4, and description thereof is omitted.

### (Operation of Optimizer)

A general operation of the optimizer 22 having the above configuration will be described. As described above, the optimizer 22 optimizes power from the solar cell module 21 and supplies the power to the electrical path 23 of the solar cell string 11. Specifically, the optimizer 22 turns off the first switch circuit 42 and turns on the second switch circuit 43 according to an instruction from the control part 46. Accordingly, the solar cell module 21 is electrically disconnected from the electrical path 23, and conduction of the electrical path 23 is ensured. In this case, the capacitor 41 is charged with the power from the solar cell module 21.

After a set period has elapsed, the first switch circuit 42 is turned on and the second switch circuit 43 is turned off according to an instruction from the control part 46. Thus, since the solar cell module 21 and the capacitor 41 are electrically connected to the electrical path 23, power equal to or higher than the power supplied by the solar cell module 21 can be supplied to the electrical path 23.

Thus, it can be understood that the optimizer 22 electrically disconnects the solar cell module 21 from the electrical path 23, and has a function (switching function) of switching between the state in which the conduction of the electrical path 23 is ensured (disconnected state) and the state in which the solar cell module 21 is electrically connected to the electrical path 23 (connected state). Therefore, in the embodiment, the control part 46 of the optimizer 22 receives the switching instruction data for instructing to perform switching to any one of the disconnected state and the connected state from the ground fault detection device 34 via the communication part 47, and executes the switching function on the basis of the received switching instruction data.

### (Details of Ground Fault Detection Device)

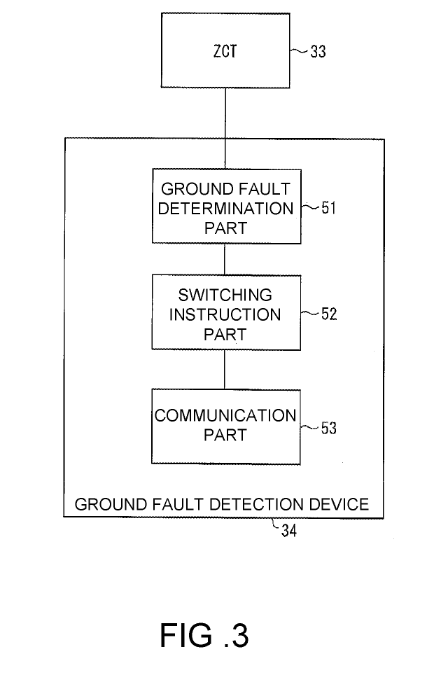

FIG. 3 is a block diagram illustrating a configuration of the ground fault detection device 34. As illustrated in FIG. 3, the ground fault detection device 34 includes a ground fault determination part 51, a switching instruction part 52, and a communication part 53. Since a function of the communication part 53 of the ground fault detection device 34 is the same as the function of the communication part 47 of the optimizer 22 illustrated in FIG. 2, description thereof will be omitted.

The ground fault determination part 51 determines the presence or absence of the ground fault in the solar cell string 11 on the basis of the value of the current from the ZCT 33. Specifically, the ground fault determination part 51 converts the current from the ZCT 33 into a voltage using a resistor or the like, determines that there is the ground fault when the value of the converted voltage is equal to or greater than a predetermined value, and determines that there is no ground fault when the value of the converted voltage is smaller than the predetermined value. The ground fault determination part 51 may output a result of the determination to the outside or may transmit the determination result to an external device.

In the embodiment, the ground fault determination part 51 sends the determination result to the switching instruction part 52. Further, the ground fault determination part 51 executes the above determination when the ground fault determination part 51 receives the fact that the switching instruction part 52 has transmitted the switching instruction data.

The switching instruction part 52 instructs the optimizer 22 to execute the switching function. Specifically, the switching instruction part 52 creates switching instruction data at a predetermined timing, and transmits the created switching instruction data to the optimizer 22 via the communication part 53. In this case, the switching instruction part 52 notifies the ground fault determination part 51 that the switching instruction part 52 has transmitted the switching instruction data. Examples of the predetermined timing include a timing when the determination result of the presence of the ground fault has been received from the ground fault determination part 51, a predetermined time, and a timing when an early morning inspection is performed.

### (Operation of Ground Fault Detection Device)

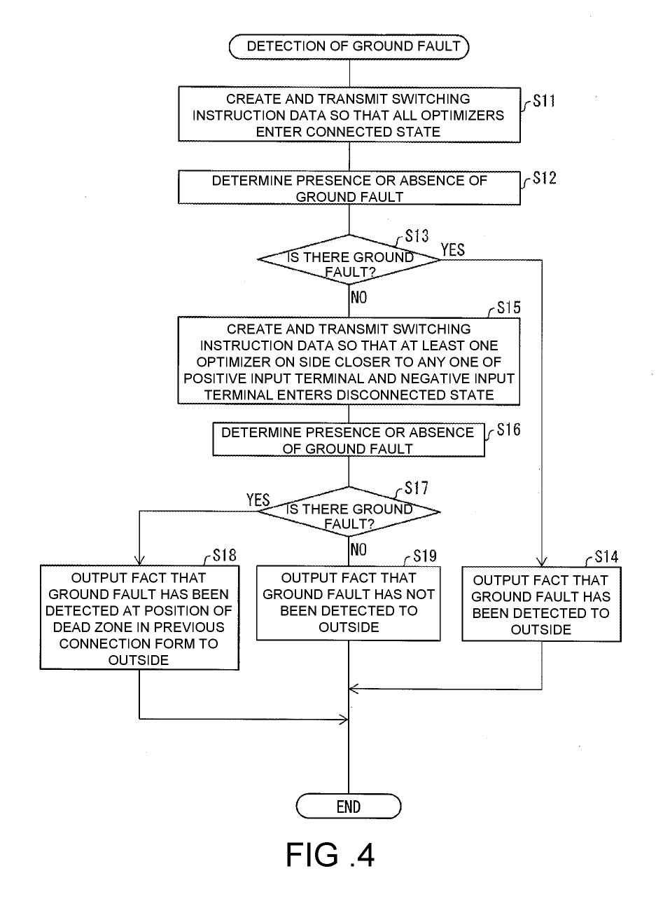

FIG. 4 is a flowchart illustrating a flow of a ground fault detection process in the ground fault detection device 34 having the above configuration (a method for controlling the ground fault detection device 34). As illustrated in FIG. 4, first, the switching instruction part 52 creates switching instruction data so that all the optimizers 22 enter the connected state, and transmits the switching instruction data to all the optimizers 22 via the communication part 53 (S11). Accordingly, the solar cell string 11 has a connection form in which all the solar cell modules 21 are connected in series.

Then, the ground fault determination part 51 determines the presence or absence of the ground fault (S12). When the ground fault determination part 51 determines that there is the ground fault (YES in S13), the ground fault determination part 51 determines that the ground fault has been detected and outputs the fact to the outside (S14). Thereafter, the process of detecting the ground fault ends.

Incidentally, in a case in which the ground fault is detected using the ZCT 33, even when the ground fault occurs at a position at which a ground voltage is about 0 (in the example of FIG. 1, a position DZ on the electrical path 23) in the solar cell string 11, it is difficult for the ground fault determination part 51 to determine that there is the ground fault. Such a position is called a dead zone.

Therefore, in the embodiment, when it is determined that there is no ground fault (NO in S13), the switching instruction part 52 creates the switching instruction data so that at least one optimizer 22 on the side closer to any one of a positive input terminal 30 and a negative input terminal enters the disconnected state, and transmits the switching instruction data to the optimizer 22 via the communication part 53 (S15; switching instruction step). Accordingly, in the solar cell string 11, the position at which the ground voltage is about 0 changes from the position DZ illustrated in FIG. 1.

Then, the ground fault determination part 51 determines the presence or absence of a ground fault (S16; ground fault determination step). When the ground fault determination part 51 determines that there is the ground fault (YES in S17), the ground fault determination part 51 determines that the ground fault has been detected at the position DZ of the dead zone in the previous connection form, and outputs the fact to the outside (S18). Thereafter, the process of detecting the ground fault ends. On the other hand, when the ground fault determination part 51 determines that there is no ground fault (NO in S16), the ground fault determination part 51 determines that the ground fault has not been detected and outputs the fact to the outside (S19). Thereafter, the process of detecting the ground fault ends.

### (Effects of Solar Power Generation System)

In the solar power generation system 1 of the embodiment, it is possible to detect a ground fault has occurred in the dead zone by changing the connection form of the solar cell modules 21. Further, even when the power from the solar cell string 11 is supplied to the power grid 80 via the PCS 12, the ground fault detection device 34 can detect the ground fault. Since the timing at which the ground fault detection device 34 operates is thus not limited, it is possible to detect a ground fault which does not always occur, such as a ground fault occurring only in the morning, a ground fault occurring only when humidity is high.

### Embodiment 2

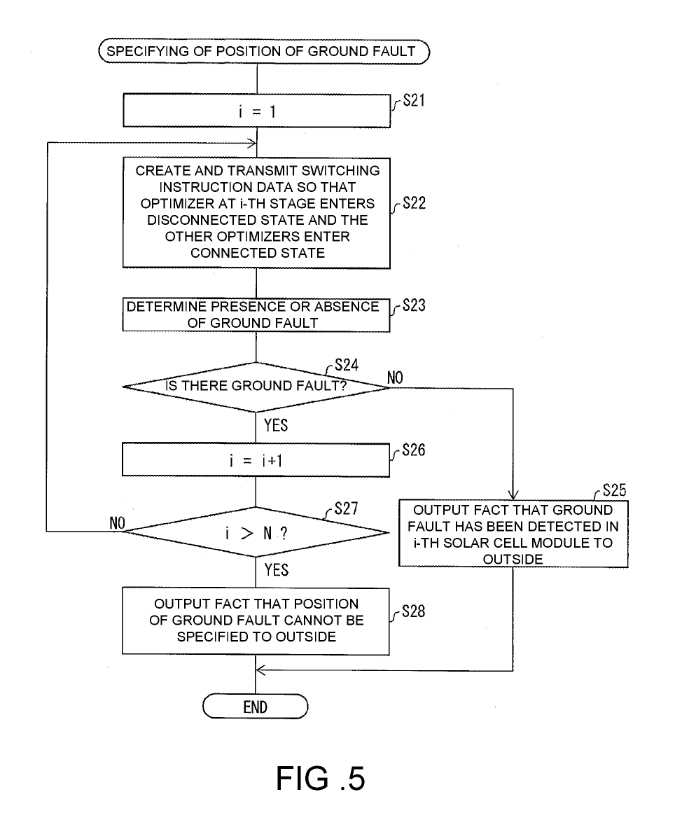

Next, another embodiment of the present invention will be described with reference to FIG. 5. A solar power generation system 1 according to the embodiment is different from the solar power generation system 1 illustrated in FIGS. 1 to 4 in that a process of specifying the position of the ground fault is added after step 14 illustrated in FIG. 4, and other configurations and processes are the same.

FIG. 5 is a flowchart illustrating a flow of a ground fault position specifying process in the ground fault detection device 34 (a method for controlling the ground fault detection device 34) according to the embodiment. As illustrated in FIG. 5, after outputting the fact that the ground fault determination part 51 has detected the ground fault to the outside (S14), the switching instruction part 52 initializes a variable i (i is an integer) to 1 (S21).

Then, the switching instruction part 52 creates the switching instruction data so that the optimizer 22 at the i-th stage enters the disconnected state and the other optimizers 22 enter the connected state, and transmits the switching instruction data to the optimizer 22 via the communication part 53 (S22; a switching instruction step). Accordingly, in the solar cell string 11, the i-th solar cell module 21 is electrically disconnected, and the other solar cell modules 21 enters the connected state in which the other solar cell modules 21 are connected in series.

Then, the ground fault determination part 51 determines the presence or absence of the ground fault (S23; ground fault determination step). When the ground fault determination part 51 determines that there is no ground fault (NO in S24), the ground fault determination part 51 determines that the ground fault has been detected in the electrically disconnected i-th solar cell module 21 and outputs the fact to the outside (S25). Thus, it is possible to specify the position of the ground fault. Thereafter, the process of specifying the position of the ground fault ends.

On the other hand, when the ground fault determination part 51 determines that there is the ground fault (YES in S24), the ground fault determination part 51 repeats the above process for the other solar cell modules 21. That is, the switching instruction part 52 increments the variable i by 1 (S26). When the incremented variable i is equal to or smaller than the number N (N is an integer) of all the solar cell modules 21 (NO in S27), the process returns to step S22 and the above process is repeated.

On the other hand, when the above process has been repeated for each of all the solar cell modules 21, that is, when the incremented variable i is larger than the number N (YES in S27), the ground fault determination part 51 determines that the position of the ground fault cannot be specified, and outputs the fact to the outside (S28). Thereafter, the process of specifying the position of the ground fault ends.

### (Effects of Solar Power Generation System)

Although the ground fault detection device of the related art can determine the presence or absence of the ground fault, it is difficult to specify the position at which the ground fault occurs in the solar cell string 11. Further, it is also difficult to specify the position at which the ground fault occurs from an appearance of the solar cell string 11.

On the other hand, in the solar power generation system 1 of the embodiment, the ground fault detection device 34 can specify the position at which the ground fault occurs by determining the presence or absence of the ground fault in cooperation with the optimizer 22.

Further, when the power from the solar cell string 11 is supplied to the power grid 80 via the PCS 12, the ground fault detection device 34 can determine the presence or absence of the ground fault and specify the position at which the ground fault occurs. Since the timing at which the ground fault detection device 34 operates is thus not limited, it is possible to determine the presence or absence of the ground fault with respect to the ground fault which does not always occur, and to specify the position at which the ground fault occurs, such that an occurrence time and an occurrence position of the ground fault can be reliably recorded. Accordingly, it is possible to clarify specifying of a repair place, a coping method, or the like, and to rapidly perform restoration work.

Further, by controlling the optimizer 22 from the communication network, more detailed failure diagnosis such as failure diagnosis, fault position specifying, and provisional operation can be performed remotely, and reduction in the amount of power generation can be suppressed.

In the embodiment, the number of solar cell modules 21 electrically disconnected from the electrical path 23 is one, but a plurality of solar cell modules 21 may be electrically disconnected. When the plurality of solar cell modules 21 are disconnected from the electrical path 23, the presence or absence of the ground fault is determined for each of the plurality of solar cell modules 21.

### Third Embodiment

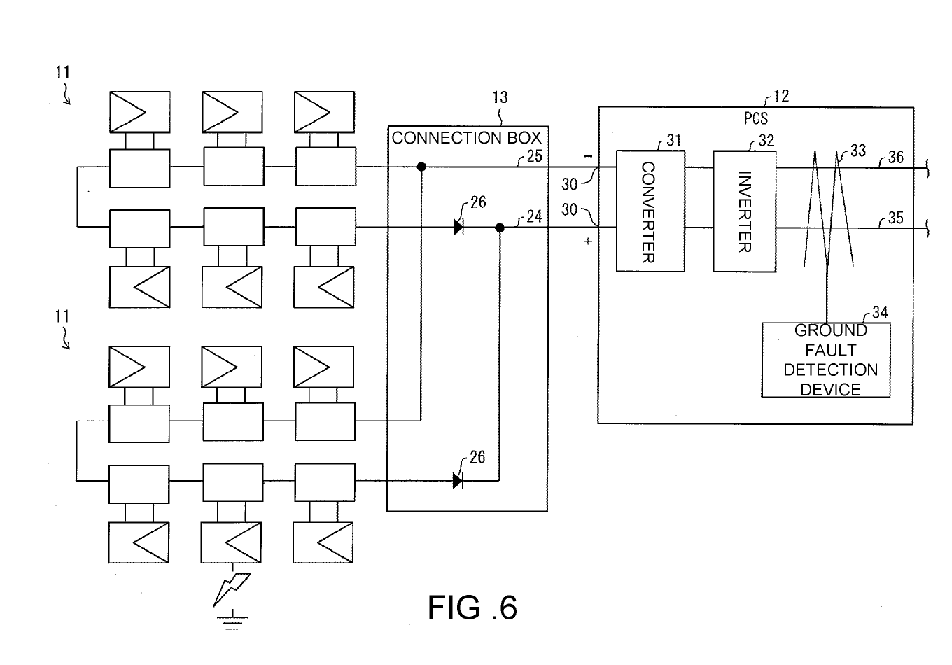

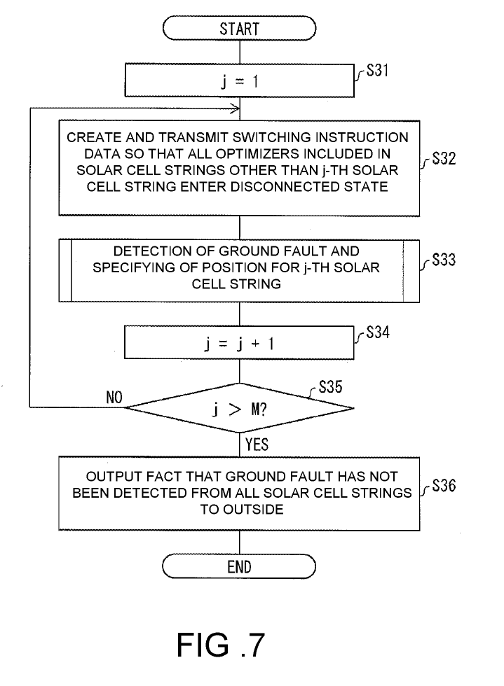

Next, another embodiment of the present invention will he described with reference to FIGS. 6 and 7.

FIG. 6 is a schematic circuit diagram illustrating a configuration of a solar power generation system according to the embodiment. The solar power generation system (direct current power supply system) 100 of the embodiment differs from the solar power generation system 1 illustrated in FIGS. 1 to 3 in that a new solar cell string 11 and a connection box 13 are added, and other configurations are the same.

The connection box 13 connects a plurality of solar cell strings 11 (two in the example of FIG. 6) in parallel. The connection box 13 connects two electrical paths 24 and 25 connected in parallel to the PCS 12. Accordingly, power from the plurality of solar cell strings 11 connected in parallel is supplied to the PCS 12. Further, in the connection box 13, a backflow prevention diode 26 for preventing a current from a certain solar cell string 11 from flowing (flowing back) to other solar cell strings 11 is provided in each solar cell string 11.

FIG. 7 is a flowchart illustrating a flow of a process regarding a ground fault in the ground fault detection device 34 of the embodiment. The process regarding the ground fault according to the embodiment is different from the process regarding the ground fault illustrated in FIGS. 4 and 5 in that the process illustrated in FIG. 7 is added, and the other processes are the same.

First, as illustrated in FIG. 7, the switching instruction part 52 initializes a variable j (j is an integer) to 1 (S31). Then, the switching instruction part 52 creates switching instruction data so that all the optimizers 22 included in the solar cell strings 11 other than a j-th solar cell string 11 enter a disconnected state, and transmits the switching instruction data to the optimizer 22 via the communication part 53 (S32).

Accordingly, only the solar cell module 21 included in the j-th solar cell string 11 supplies power to the PCS 12. Further, a current from the j-th solar cell string 11 flows to the input terminal 30 of the PCS 12 without flowing to the other solar cell strings 11 due to the backflow prevention diode 26 of the connection box 13. Therefore, this configuration can be regarded as a configuration as illustrated in FIG. 1 in which only the j-th solar cell string 11 is connected to the PCS 12. Even in a configuration in which there is no backflow prevention diode 26, it is also possible to prevent a current from flowing from the j-th solar cell string 11 to the other solar cell strings 11 under the control of the optimizer 22.

For the j-th solar cell string 11, the ground fault detection process (S11 to S19) illustrated in FIG. 4 and the ground fault position specifying process (S21 to S28) illustrated in FIG. 5 are performed (S33).

Then, the above process is repeated for the other solar cell strings 11. That is, the switching instruction part 52 increments the variable j by 1 (S34). When the incremented variable j is equal to or smaller than the number M (M is an integer) of all the solar cell strings 11 (NO in S35), the process returns to step S32 and the above process is repeated.

Meanwhile, when the above process has been repeated for each of all the solar cell strings 11, that is, when the incremented variable i is larger than the above number M (YES in S35), the ground fault determination part 51 determines that the ground fault has not been detected from all the solar cell strings 11 and outputs the fact to the outside (S36). Thereafter, the process of specifying the position of the ground fault ends.

Therefore, in the solar power generation system 100 including the plurality of solar cell strings 11, it is possible to determine the presence or absence of the ground fault for each of the solar cell strings 11, and as a result, it is possible to accurately detect the ground fault.

In the embodiment, the number of solar cell strings 11 electrically connected to the input terminal 30 of the PCS 12 is one, but the number of solar cell strings 11 electrically connected to the input terminal 30 of the PCS 12 may be plural. When the number of solar cell strings 11 electrically connected to the input terminal 30 of the PCS 12 is plural, the presence or absence of a ground fault is determined for each of the plurality of solar cell strings 11.

### (Additional Notes)

In the above embodiment, the ground fault is detected using the ZCT 33, but the present invention is not limited thereto. The present invention can be applied to detection of a ground fault using various methods, such as detections of a ground fault using resistance ground, and detection of a ground fault using an insulation measurement instrument such as a Megger (an insulation resistance meter).

In the above embodiment, the ground fault detection device 34 is provided inside the PCS 12, but the present invention is not limited thereto. For example, the ground fault detection device 34 may be provided outside the PCS 12, may be provided inside the connection box 13, or may be provided inside the optimizer 22.

Further, in the above embodiment, the switching instruction part 52 is provided in the ground fault detection device 34, but the present invention is not limited thereto. For example, the switching instruction part 52 may be provided in an external communication device.

Further, in the above embodiment, the optimizer 22 is provided in each solar cell module 21, but the present invention is not limited thereto, and the optimizer 22 may be provided for the plurality of solar cell modules 21. In this case, the ground fault detection device 34 determines that a ground fault occurs in any of the plurality of solar cell modules 21.

Further, in the above embodiment, the optimizer 22 is used, but the present invention is not limited thereto, and any switch capable of electrically disconnecting the solar cell module 21 from the solar cell string 11 and communicating with the ground fault detection device 34 can be used.

Further, in the above embodiment, the present invention is applied to the solar power generation system, but the present invention is not limited thereto and may be applied to any power supply system including a direct current power source and a power conversion device that converts power from the direct current power source. Examples of the direct current power supply may include a fuel cell device capable of obtaining electrical energy (direct current power) using hydrogen fuel according to an electrochemical reaction between hydrogen fuel and oxygen in air, a storage battery that accumulates electric energy, and a power storage device such as a capacitor, in addition to the solar power generation device.

### [Implementation Example Using Software]

A control block of the optimizer 22 and the ground fault detection device 34 (particularly, the control part 46, the ground fault determination part 51, and the switching instruction part 52) may be realized by a logic circuit (hardware) formed in an integrated circuit (IC chip) or may be realized by software using a central processing unit (CPU).

In the latter case, the optimizer 22 and the ground fault detection device 34 include, for example, a CPU that executes instructions of a program which is software for realizing each function, a read only memory (ROM) or a storage device (these are referred to as a “recording medium”) in which the program and various pieces of data are recorded to be readable by a computer, and a random access memory (RAM) for developing the above program. The object of the present invention is achieved by the computer (or the CPU) reading the program from the recording medium and executing the program. As the recording medium, a “non-transitory tangible medium”, such as a tape, a disk, a card, a semiconductor memory, a programmable logic circuit, or the like can be used. Further, the program may be supplied to the computer via any transmission medium (communication network, broadcast waves or the like) capable of transmitting the program. The present invention can also be realized in the form of a data signal embedded in a carrier wave, in which the program is embodied by electronic transmission.

As described above, the ground fault detection device according to the present invention is applied to a direct current power supply system including a load device that converts or consumes direct current power input to an input terminal, an electrical path connected to the input terminal, and a direct current power supply string in which a plurality of direct current power supply parts are connected in series, and the direct current power supply part includes a direct current power supply module that generates or charges and discharges power, and a switch that connects or disconnects the direct current power supply module to and from the electrical path. The ground fault detection device includes the switching instruction part that instructs the switch to switch between the connection and the disconnection, and the ground fault determination part that determines the presence or absence of the ground fault of the direct current power supply string after the instruction of the switching instruction part.

According to the above configuration, when the direct current power supply module in which a certain switch has been provided is disconnected from the electrical path according to the instruction from the switching instruction part, the connection form of the direct current power supply module in the direct current power supply string is changed. Since the presence or absence of the ground fault of the direct current power supply string is determined after the change of the connection form, the presence or absence of the ground fault in various connection forms can be determined.

For example, when it is determined that there is a ground fault in a certain connection form and it is determined that there is no ground fault in another connection form, it is possible to determine that the ground fault occurs in the direct current power supply module disconnected from the electrical path in the other connection form.

Further, in a case in which the ground fault is detected using a zero-phase current transformer, even when the ground fault occurs at a position (dead zone) where the ground voltage is about 0 in the direct current power supply string, it is difficult to detect the ground fault. On the other hand, according to the present invention, since the position at which the ground voltage is about 0 is changed by changing the connection form, it is possible to detect the ground fault at the dead zone in the connection form before the change.

As described above, the ground fault detection device according to the present invention has an effect that the ground fault can be accurately detected.

In the ground fault detection device according to the present invention, the switching instruction part may instruct at least one of the switches to disconnect the direct current power supply module from the electrical path, and then, the ground fault determination part may determine the presence or absence of the ground fault. By repeating this operation with respect to all the switches, it is possible to specify the direct current power supply module in which the ground fault occurs.

The number of direct current power supply modules to be disconnected from the electrical path may be one or plural. When the plurality of direct current power supply modules are disconnected from the electrical path, the presence or absence of a ground fault is determined for each of the plurality of direct current power supply modules.

In the ground fault detection device according to the present invention, a plurality of direct current power supply strings connected in parallel may be connected to the input terminal via the electrical path, the ground fault detection device may detect a ground fault in the plurality of direct current power supply strings, and the switching instruction part instructs all the switches included in the direct current power supply string other than the certain direct current power supply string to disconnect the direct current power supply module from the electrical path, and then, the ground fault determination part may determine the presence or absence of the ground fault. By repeating this with respect to all the direct current power supply strings, it is possible to detect the ground fault for each of the direct current power supply strings, and as a result, to accurately detect the ground fault even in the power supply system including the plurality of direct current power supply strings.

The number of the certain direct current power source strings may be one or plural. When the number of the certain direct current power source strings is plural, a ground fault is detected for each of the plurality of direct current power supply strings.

The ground fault detection device having the above configuration may be included in the load device in the direct current power supply system or in the switch in the direct current power supply system.

A method for controlling a ground fault detection device according to the present invention is a method for controlling a ground fault detection device that is applied to the direct current power supply system having the above configuration, and includes a switching instruction step of instructing the switch to switch between connection and disconnection, and a ground fault determination step of determining the presence or absence of a ground fault of the direct current power supply string after the instruction of the switching instruction part.

According to the above method, the same advantageous effect as in the ground fault detection device can be achieved.

The ground fault detection device according to the present invention may be realized by a computer. In this case, a control program of the ground fault detection device that causes the computer to realize the ground fault detection device by causing the computer to operate as each part included in the ground fault detection device, and a computer-readable recording medium having the control program recorded thereon are included in the scope of the present invention.

A communication device according to the present invention is applied to a direct current power supply system including the load device having the above configuration, the electrical path having the above configuration, the direct current power supply string having the above configuration, and the ground fault detection device that detects a ground fault of the direct current power supply string, the communication device includes a switching instruction part that instructs the switch to switch between connection and disconnection, and the switching instruction part notifies the ground fault detection device that the switching has been instructed.

According to the above configuration, when the direct current power supply module in which the switch has been provided is disconnected from the electrical path according to the switching instruction from the switching instruction part, the connection form of the direct current power supply module in the direct current power supply string is changed. Since the ground fault detection device can determine the presence or absence of the ground fault of the direct current power supply string after the change of the connection form according to the notification indicating that the switching has been instructed, it is possible to determine the presence or absence of the ground fault in the various connection forms. As a result, it is possible to accurately detect a ground fault.

A method for controlling a communication device according to the present invention is a method for controlling a communication device that is applied to the direct current power supply system having the above-described configuration, and includes a switching instruction step of instructing the switch to switch between connection and disconnection, and the switching instruction step includes notifying the ground fault detection device that the switching has been instructed.

According to the above method, the same advantageous effect as in the communication device can be achieved.

The communication device according to the present invention may be realized by a computer. In this case, a control program of a communication device that causes a computer to realize the communication device by causing the computer to operate as a switching instruction part included in the communication device, and a computer-readable recording medium having the control program recorded thereon are also included in the scope of the present invention.

The present invention is not limited to the above-described embodiments, and various modifications can be made within the scope indicated in the claims, and embodiments obtained by appropriately combining respective technical means disclosed in different embodiments are also included in the technical scope of the present invention.

### REFERENCE SIGNS LIST

1, 100 Solar power generation system (direct current power supply system)

11 Solar cell string (direct current power supply string)

12 PCS (load device)

13 Connection box

20 Solar cell part (direct current power supply part)

21 Solar cell module (direct current power supply module)

22 Optimizer (switch)

26 Backflow prevention diode

33 ZCT

34 Ground fault detection device

41 Capacitor

42 First switch circuit

43 Second switch circuit

46 Control part

47, 53 communication part

51 Ground fault determination part

52 Switching instruction part

80 Power grid (load device)

1. A ground fault detection device that is applied to a direct current power supply system, the direct current power supply system comprising
a load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power and switches that connect or disconnect the direct current power supply module to and from the electrical path, the ground fault detection device comprising:
a switching instruction part that instructs the switches to switch between connection and disconnection; and
a ground fault determination part that determines presence or absence of a ground fault of the direct current power supply string after the switching instruction part instructed the switches.

2. The ground fault detection device according to claim 1, wherein the switching instruction part instructs at least one of the switches to disconnect the direct current power supply module from the electrical path, and then the ground fault determination part determines the presence or absence of the ground fault.

3. The ground fault detection device according to claim 1,
wherein a plurality of direct current power supply strings connected in parallel are connected to the input terminal via the electrical path,
the ground fault detection device detects the ground fault in the plurality of direct current power supply strings, and
the switching instruction part instructs all the switches comprised in the direct current power supply strings other than one of the direct current power supply strings to disconnect the direct current power supply module from the electrical path, and then the ground fault determination part determines the presence or absence of the ground fault.

4. A load device in a direct current power supply system, the direct current power supply system comprising
the load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power and switches that connect or disconnect the direct current power supply module to and from the electrical path, the load device comprising:
the ground fault detection device according to claim 1.

5. A switch in a direct current power supply system, the direct current power supply system comprising
a load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power, and the switch that connects or disconnects the direct current power supply module to or from the electrical path, the switch comprising:
the ground fault detection device according to claim 1.

6. A communication device that is applied to a direct current power supply system, the direct current power supply system comprising
a load device that converts or consumes direct current power input to an input terminal,
an electrical path connected to the input terminal,
a direct current power supply string in which a plurality of direct current power supply parts are connected in series, each of the direct current power supply parts comprising a direct current power supply module that generates or charges and discharges power, and a switch that connects or disconnects the direct current power supply module to or from the electrical path, and
a ground fault detection device that detects a ground fault of the direct current power supply string, the communication device comprising:
a switching instruction part that instructs the switches to switch between connection and disconnection,
wherein the switching instruction part notifies the ground fault detection device that the switching has been instructed.

7. A non-transitory computer-readable recording medium comprising a control program causing a computer to function as the ground fault detection device according to claim 1, the control program causing the computer to function as each of the parts.

8. A non-transitory computer-readable recording medium comprising a control program causing a computer to function as the communication device according to claim 6, the control program causing the computer to function as the switching instruction part.

9. A method of controlling a ground fault detection device that is applied to a direct current power supply system, the direct current power supply system comprising
a load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power and switches that connect or disconnect the direct current power supply module to or from the electrical path, the method comprising:
a switching instruction step of instructing the switches to switch between connection and disconnection; and
a ground fault determination step of determining presence or absence of a ground fault of the direct current power supply string after instructing the switches in the switching instruction step.

10. A method of controlling a communication device that is applied to a direct current power supply system, the direct current power supply system comprising
a load device that converts or consumes direct current power input to an input terminal,
an electrical path connected to the input terminal,
a direct current power supply string in which a plurality of direct current power supply parts are connected in series, each of the direct current power supply parts comprising a direct current power supply module that generates or charges and discharges power and switches that connect or disconnect the direct current power supply module to or from the electrical path, and
a ground fault detection device that detects a ground fault of the direct current power supply string, the method comprising:
a switching instruction step of instructing the switches to switch between connection and disconnection,
wherein the switching instruction step comprises notifying the ground fault detection device that the switching has been instructed.

11. The ground fault detection device according to claim 2,
wherein a plurality of direct current power supply strings connected in parallel are connected to the input terminal via the electrical path,
the ground fault detection device detects the ground fault in the plurality of direct current power supply strings, and
the switching instruction part instructs all the switches comprised in the direct current power supply strings other than one of the direct current power supply strings to disconnect the direct current power supply module from the electrical path, and then the ground fault determination part determines the presence or absence of the ground fault.

12. A load device in a direct current power supply system, the direct current power supply system comprising
the load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power and switches that connect or disconnect the direct current power supply module to and from the electrical path, the load device comprising:
the ground fault detection device according to claim 2.

13. A load device in a direct current power supply system, the direct current power supply system comprising
the load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power and switches that connect or disconnect the direct current power supply module to and from the electrical path, the load device comprising:
the ground fault detection device according to claim 3.

14. A load device in a direct current power supply system, the direct current power supply system comprising
the load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power and switches that connect or disconnect the direct current power supply module to and from the electrical path, the load device comprising:
the ground fault detection device according to claim 11.

15. A switch in a direct current power supply system, the direct current power supply system comprising
a load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power, and the switch that connects or disconnects the direct current power supply module to or from the electrical path, the switch comprising:
the ground fault detection device according to claim 2.

16. A switch in a direct current power supply system, the direct current power supply system comprising
a load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power, and the switch that connects or disconnects the direct current power supply module to or from the electrical path, the switch comprising:
the ground fault detection device according to claim 3.

17. A switch in a direct current power supply system, the direct current power supply system comprising
a load device that converts or consumes direct current power input to an input terminal,
an electrical path connected to the input terminal, and
a direct current power supply string in which a plurality of direct current power supply parts are connected in series, each of the direct current power supply parts comprising a direct current power supply module that generates or charges and discharges power, and the switch that connects or disconnects the direct current power supply module to or from the electrical path, the switch comprising:
the ground fault detection device according to claim 11.

18. A non-transitory computer-readable recording medium comprising a control program causing a computer to function as the ground fault detection device according to claim 2, the control program causing the computer to function as each of the parts.

19. A non-transitory computer-readable recording medium comprising a control program causing a computer to function as the ground fault detection device according to claim 3, the control program causing the computer to function as each of the parts.

20. A non-transitory computer-readable recording medium comprising a control program causing a computer to function as the ground fault detection device according to claim 11, the control program causing the computer to function as each of the parts.
